(19) United States
(12) Patent Application Publication
(10) Pub. No.: US 2018/0122469 A1
(43) Pub. Date: May 3, 2018

(54) RESISTIVE MEMORY APPARATUS

(71) Applicant: SK hynix Inc., Icheon-si Gyeonggi-do (KR)

(72) Inventor: Choung Ki SONG, Yongin-si Gyeonggi-do (KR)

(73) Assignee: SK hynix Inc., Icheon-si Gyeonggi-do (KR)

(21) Appl. No.: 15/474,079

(22) Filed: Mar. 30, 2017

(30) Foreign Application Priority Data
Nov. 1, 2016 (KR) 1020160144595

(51) Int. Cl. G11C 13/00

(52) U.S. Cl. CPC G11C 13/0069; G11C 13/0061; G11C 13/004; G11C 13/0038

(57) ABSTRACT

A resistive memory apparatus of the technology includes a memory circuit divided into a plurality of partitions and an input/output (I/O) circuit including a plurality of power supply circuits and an output circuit. The plurality of power supply circuits are configured in one-to-one correspondence with the plurality of partitions.

### CROSS-REFERENCES TO RELATED APPLICATION

The present application claims priority under 35 U.S.C. § 119(a) to Korean application number 10-2016-0144595, filed on Nov. 1, 2016, in the Korean Intellectual Property Office, which is incorporated herein by reference in its entirety.

### BACKGROUND

### 1. Technical Field

Various embodiments may generally relate to a semiconductor integrated apparatus, and more particularly, to a resistive memory apparatus.

### 2. Related Art

Resistive memory apparatuses may be a memory apparatus in which a data storage material layer is arranged between a pair of electrodes and data is programmed through changing a resistance state of the data storage material layer by an applied current or voltage.

The resistive memory apparatuses have been increasingly highly integrated and an amount of current consumption required for operation of the memory apparatuses has also been increased.

A read/write circuit configured to operate the resistive memory apparatus may be disposed on one side of a memory region. A length of a wiring which couples the read/write circuit and the memory region may be changed according to a position of a memory cell in the memory region.

Parasitic capacitance, wiring resistance, and the like on the wiring may serve as factors which change operation characteristics of the memory cells.

### SUMMARY

In an embodiment of the present disclosure, a resistive memory apparatus may include: a memory circuit divided into a plurality of partitions; and an input/output (I/O) circuit including a plurality of power supply circuits and an output circuit. The plurality of power supply circuits may be configured in one-to-one correspondence with the plurality of partitions.

In another embodiment of the present disclosure, a resistive memory apparatus may include: a memory circuit divided into a plurality of partitions; a plurality of power supply circuits each arranged next to at least one partition of the plurality of partitions; and an output circuit to which output terminals of the plurality of power supply circuits are commonly coupled.

These and other features, aspects, and embodiments are described below in the section entitled “DETAILED DESCRIPTION”.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a configuration diagram illustrating a resistive memory apparatus according to an embodiment of the present disclosure;

FIG. 2 is a configuration diagram illustrating a power supply circuit according to an embodiment of the present disclosure;

FIG. 3 is a configuration diagram illustrating an output circuit according to an embodiment of the present disclosure;

FIG. 4 is a configuration diagram illustrating a partition and a selection circuit according to an embodiment of the present disclosure;

FIGS. 5 to 9 are configuration diagrams illustrating resistive memory cells according to an embodiment of the present disclosure; and

FIG. 10 illustrates a block diagram of an example system employing a semiconductor device in accordance with the various embodiments discussed above with relation to FIGS. 1-9.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The present disclosure is described herein with reference to cross-section and/or plan illustrations of idealized embodiments of the present disclosure. However, embodiments of the present disclosure should not be construed as limiting the inventive concept. Although a few embodiments of the present disclosure will be shown and described, it will be appreciated by those of ordinary skill in the art that changes may be made to these embodiments without departing from the principles and spirit of the present disclosure.

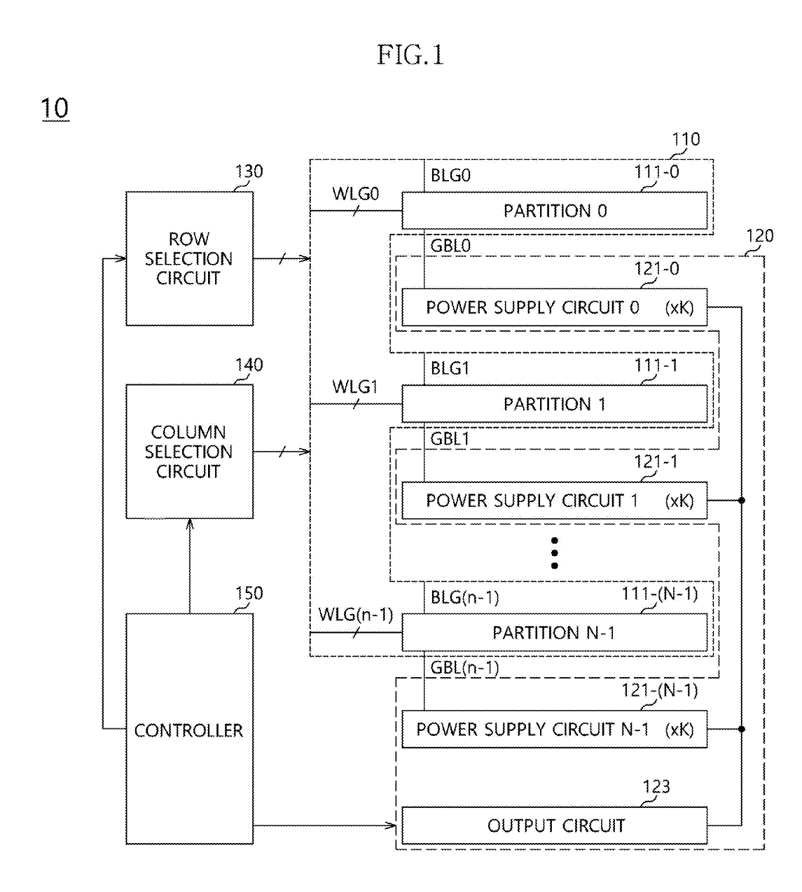

FIG. 1 is a configuration diagram illustrating a resistive memory apparatus according to an embodiment.

Referring to FIG. 1, a resistive memory apparatus 10 according to an embodiment may include a memory circuit 110, an input/output (I/O) circuit 120, a row selection circuit 130, a column selection circuit 140, and a controller 150.

The memory circuit 110 may be divided into a plurality of partitions 111-0 to 111-(N−1) which may be collectively referred to as 111.

Each of the partitions 111-0 to 111-(N−1) may include a plurality of memory cells arranged on intersections of word line groups WLG0 to WLG(n−1) where each of the word line groups WLG0 to WLG(n−1) may include at least one word line, and bit line groups BLG0 to BLG(n−1) where each of the bit line groups BLG0 to BLG(n−1) may include a plurality of bit lines.

The memory cells constituting each of the partitions 111-0 to 111-(N−1) of the memory circuit 110 may be implemented using a memory cell in which a level of data stored is determined according to a resistance state of a data storage node. The memory cells may be configured including a phase-change random access memory (PRAM) cell using a chalcogenide alloy, a magnetic RAM (MRAM) cell using a tunneling magneto-resistive (TMR) effect, a resistive RAM (RERAM) cell using a transition metal oxide, a polymer RAM cell, a RAM cell using perovskite, a ferroelectric RAM (FRAM) cell using a ferroelectric capacitor, and the like, but the memory cells are not limited thereto.

Each of the memory cells constituting the partition 111-0 to 111-(N−1) of the memory circuit 110 may be a single level cell (SLC) which stores 1-bit of data in one memory cell or a multi-level cell (MLC) which stores 2-bits or more of data in one memory cell.

The I/O circuit 120 may include a power supply circuit 121 and an output circuit 123. The power supply circuit 121 may include a plurality of power supply circuits 121-0 to 121-(N−1).

In an embodiment, the plurality of power supply circuits may be configured in a one-to-one correspondence with the partitions 111-0 to 111-(N−1). A specific power supply circuit among the power supply circuits 121-0 to 121-(N−1) configured to supply an operation voltage to a specific partition among the partitions 111-0 to 111-(N−1) may be arranged to be physically close to, for example next to, the specific partition 111-0 to 111-(N−1).

In an embodiment, the partitions 111-0 to 111-(N−1) and the power supply circuits 121-0 to 121-(N−1) may be alternately arranged in a physical manner such that partition 111-0 is next to power supply circuit 121-0, power supply circuit 121-0 is between partition 111-0 and partition 111-1, etc., but this is not limited thereto.

The output circuit 123 may be configured to be arranged on one side of the memory circuit 110 and the output terminals of the power supply circuits 121-0 to 121-(N−1) may be commonly coupled to the output circuit 123.

The partitions 111-0 to 111-(N−1) and the power supply circuits 121-0 to 121-(N−1) corresponding to the partitions 111-0 to 111-(N−1), where each of the power supply circuits 121-0 to 121-(N−1) may be configured to supply power voltages to global bit lines GBL0 to GBL(n−1), may be coupled through the global bit lines GBL0 to GBL(n−1). The output terminals of the power supply circuits 120-1 to 121-(N−1) may be coupled to the output circuit 123 through other wirings other than the global bit lines GBL0 to GBL(n−1).

In an embodiment, each of the partitions 111-0 to 111-(N−1) may be divided into a plurality of blocks, for example, K blocks in bit units.

The row selection circuit 130 and the column selection circuit 140 may be address decoders and may be configured to receive address signals. The row selection circuit 130 may receive a row address of a memory cell to be accessed, for example, a word line address and decode the received word line address through control of the controller 150. The column selection circuit 140 may receive a column address of a memory cell to be accessed, for example, a bit line address and decode the received bit line address through control of the controller 150.

The controller 150 may control an overall operation of the resistive memory apparatus 10 so that data may be transmitted and received between a host apparatus (not shown) and the resistive memory apparatus 10.

In a read operation and a write operation of the memory circuit 110, an operation voltage may be supplied to a selected memory cell of a selected partition. Because the power supply circuits 121-0 to 121-(N−1) are arranged close to the partitions 111-0 to 111-(N−1) in a one-to-one correspondence form, the operation voltage supplied to a selected partition 111-0, for example, may have a uniform level with respect to all the partitions 111-0 to 111-(N−1).

Accordingly, the same operation voltage may be provided to all the memory cells in the partition without a voltage drop due to a parasitic capacitance component and wiring resistance on a connection wiring between the I/O circuit and the memory cell.

The global bit line GBL may be slightly affected by the wiring resistance and parasitic capacitance. Accordingly, read margins of the partitions may be equally maintained by coupling the output terminals of the power supply circuits 121-0 to 121-(N−1) and the output circuit 123 through wirings other than the global bit line (GBL).

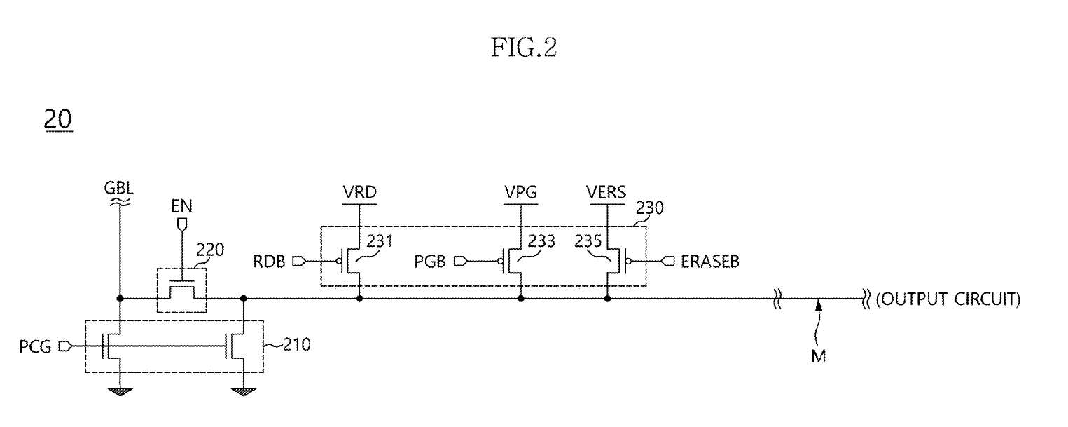

FIG. 2 is a configuration diagram illustrating a power supply circuit according to an embodiment.

Referring to FIG. 2, a power supply circuit 20, which may correspond to the power supply circuit 121 of FIG. 1, according to an embodiment may include a precharge circuit 210, a driving circuit 220, and a power circuit 230.

The precharge circuit 210 may be configured to be electrically coupled to a global bit line GBL extending from a partition 111 (see FIG. 1) and precharge a voltage of the global bit line GBL to a fixed level in response to a precharge command PCG.

The driving circuit 220 may be configured to be electrically coupled to the global bit line GBL and to electrically couple or disconnect the global bit line GBL and the power circuit 230 in response to an enable signal EN.

The power circuit 230 may include a read voltage providing unit 231, a first write voltage providing unit 233, and a second write voltage providing unit 235.

The read voltage providing unit 231 may be configured to allow a read voltage VRD to be applied to the global bit line GBL in response to a read command RDB.

The first write voltage providing unit 233 may be configured to allow a first write voltage VPG to be applied to the global bit line GBL in response to a first write command PGB. In an embodiment, the first write command PGB may be a program command for programming a first level of data.

The second write voltage providing unit 235 may be configured to allow a second write voltage VERS to be applied to global bit line GBL in response to a second write command ERASERB. In an embodiment, the second write command ERASERB may be a programming command for programming a second level of data. Accordingly, each of the plurality of power supply circuits 121 (see FIG. 1) may be configured to supply at least one of the read voltage VRD, the first write voltage VPG, and the second write voltage VERS to the global bit line GBL of the partition 111 corresponding to the power supply circuit 121.

The global bit line GBL may be electrically coupled to the output circuit 123 (see FIG. 1) through a specific wiring M. The output terminals of the power supply circuits 121-0 to 121-(N−1) (see FIG. 1) may be commonly coupled to the output circuit 123 through the specific wirings M.

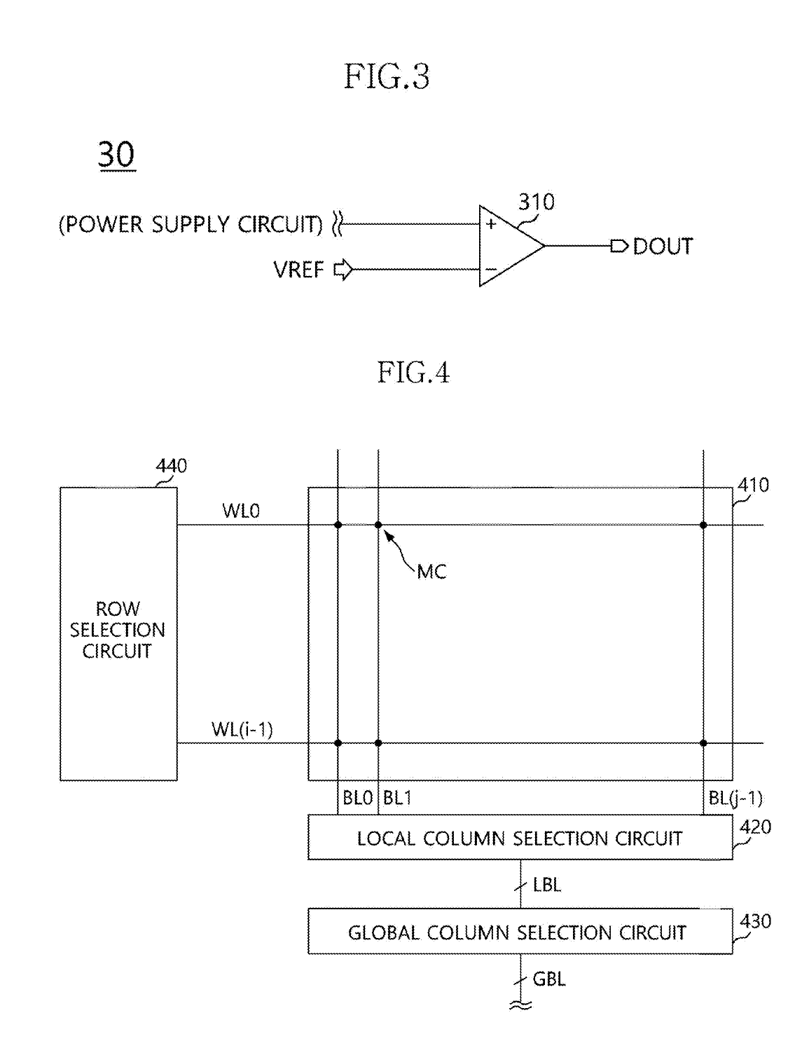

FIG. 3 is a configuration diagram illustrating an output circuit according to an embodiment.

In an embodiment, an output circuit 30 may include a comparison circuit 310 configured to generate output data DOUT by comparing a voltage applied to the output terminal of the power supply circuit 20 with a reference voltage VREF in a read operation.

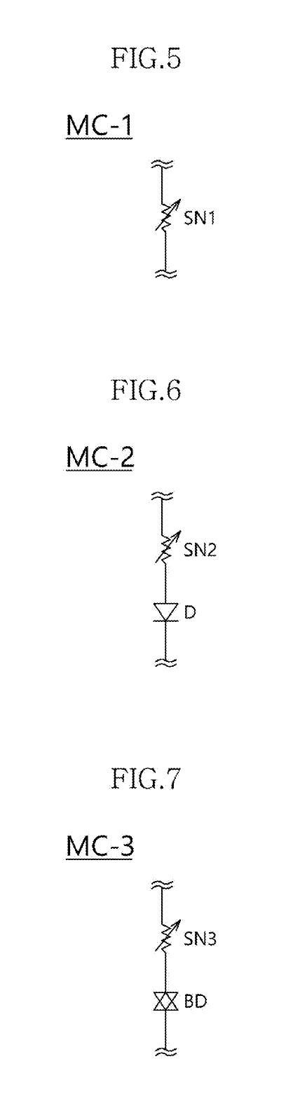

FIG. 4 is a configuration diagram illustrating a partition and a selection circuit according to an embodiment.

Referring to FIG. 4, a partition 410 according to an embodiment may include a plurality of memory cells MC, resistive memory cells for example, coupled between at least one word line WL0 to WL(i−1), for example, a word line group and at least one bit line BL0 to BL(j−1), for example, a bit line group.

The bit line BL0 to BL(j−1) may have, for example, a hierarchy structure. In this example, the column selection circuit 140 (see FIG. 1) may include a local column selection circuit 420 and a global column selection circuit 430.

The local column selection circuit 420 may be configured to control selection of local bit lines LBL by receiving a column address according to control of the controller 150 (see FIG. 1). The global column selection circuit 430 may be configured to control selection of the global bit lines GBL by receiving the column address according to control of the controller 150.

Accordingly, a word line WL of a memory cell to be accessed may be activated through a row selection circuit 440. The phrase “activation of the word line WL” may mean to enable memory cells coupled to the word line WL to perform at least one operation by providing a read voltage, a write voltage, and a verifying voltage to the word line WL.

The bit line BL of the memory cell to be accessed may be activated through the global column selection circuit and the local column selection circuit. The phrase “activation of the bit line BL” may mean that a path of the bit line BL is activated through coupling of a switch and the like to the bit line BL. When the bit line is activated, data may be read from or written in a memory cell corresponding to the activated path of the bit line BL.

Returning briefly to FIG. 1, in the technology, the bit line operation voltage for operating the resistive memory apparatus 10 may be supplied according to the partitions 111 and signals of the partitions 111 may be provided to the output circuit 123 through the wirings M which have a smaller wiring resistance and parasitic capacitance than the global bit line GBL.

Accordingly, the operation voltage having a uniform level may be provided to the partitions 111 regardless of the positions of the partitions 111.

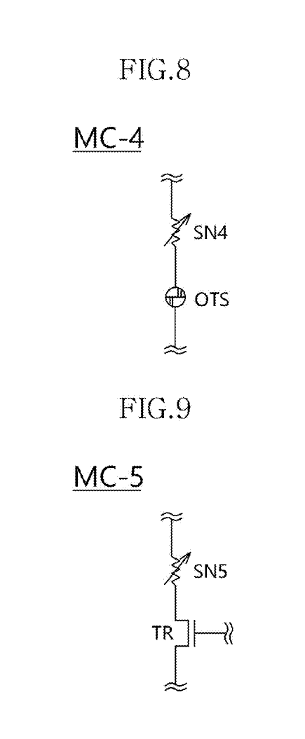

FIGS. 5 to 9 are configuration diagrams illustrating resistive memory cells according to embodiments.

FIG. 5 illustrates an example of a memory cell MC-1 including a variable resistor operating as a storage node SN1 arranged between a pair of wirings.

FIG. 6 illustrates an example of a memory cell MC-2 including a storage node SN2 and a diode D operating as an access element electrically coupled between a pair of wirings. In the embodiment, the diode D may be selected from a vertical channel transistor and a horizontal channel transistor.

FIG. 7 illustrates an example of a memory cell MC-3 including a storage node SN3 and a bidirectional diode BD operating as an access element electrically coupled between a pair of wirings.

FIG. 8 illustrates an example of a memory cell MC-4 including a storage node SN4 and an ovonic threshold switching device OTS operating as an access element electrically coupled between a pair of wirings.

FIG. 9 illustrates an example of a memory cell MC-5 including a storage node SN5 and a transistor TR operating as an access element electrically coupled between a pair of wirings. In the embodiment, the transistor TR may be a MOS transistor, for example, a vertical channel transistor.

The storage nodes SN1 to SN5 in FIGS. 5 to 9 may be configured using a material having a resistance value that is changed according to an applied current amount. The pair of wirings may include a word line and a bit line.

When the memory cell MC constituting the memory circuit 110 is accessed for a read or write operation, because a bit line-side power supply circuit is provided in each partition, the stable operation voltage may be uniformly provided to the partition.

The above described embodiments of the present disclosure are intended to illustrate and not to limit the present disclosure. Various alternatives and equivalents are possible. The disclosure is not limited by the embodiments described herein. Nor is the disclosure limited to any specific type of semiconductor device. Other additions, subtractions, or modifications are obvious in view of the present disclosure and are intended to fall within the scope of the appended claims.

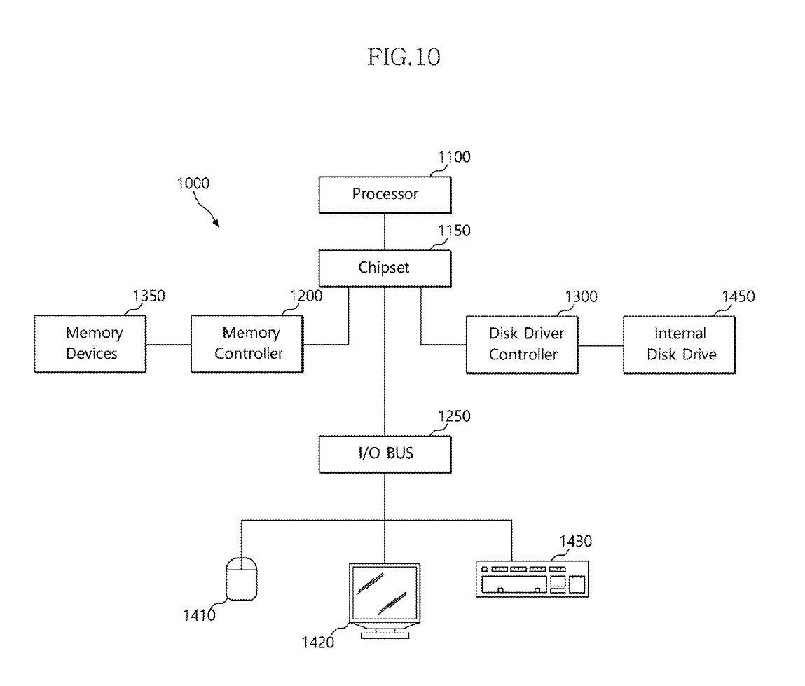

The semiconductor devices and/or a resistive memory apparatus above (see FIGS. 1-9) are particularly useful in the design of memory devices, processors, and computer systems. For example, referring to FIG. 10, a block diagram of a system employing a semiconductor device and/or a resistive memory apparatus in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one semiconductor device and/or a resistive memory apparatus as discussed above with reference to FIGS. 1-9. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor device and/or a resistive memory apparatus as discussed above with relation to FIGS. 1-9, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 10 is merely one example of a system 1000 employing a semiconductor device and/or a resistive memory apparatus as discussed above with relation to FIGS. 1-9. In alternate embodiments, such as, for example but not limited to, cellular phones or digital cameras, the components may differ from the embodiments illustrated in FIG. 10.

What is claimed is:

1. A resistive memory apparatus comprising:
a memory circuit divided into a plurality of partitions; and
an input/output (I/O) circuit including a plurality of power supply circuits and an output circuit,
wherein the plurality of power supply circuits are configured in one-to-one correspondence with the plurality of partitions.

2. The resistive memory apparatus of claim 1, wherein each of the plurality of partitions includes a plurality of resistive memory cells coupled between at least one word line and at least one bit line, and each of the plurality of power supply circuits is configured to supply a power voltage to the bit line.

3. The resistive memory apparatus of claim 2, wherein each resistive memory cell includes at least one of a single level cell which stores 1-bit of data in a single memory cell or a multi-level cell which stores 2 bits or more of data in a single memory cell.

4. The resistive memory apparatus of claim 1, wherein each of the plurality of partitions includes a plurality of resistive memory cells coupled between at least one word line and at least one bit line, and each of the plurality of power supply circuits is configured to supply a read voltage, a first write voltage, and a second write voltage to the bit line of a partition corresponding to the power supply circuit.

5. The resistive memory apparatus of claim 4, wherein the memory cells include at least one of a phase-change random access memory cell using a chalcogenide alloy, a magnetic random access memory (RAM) cell using a tunneling magneto-resistive effect, a resistive RAM cell using a transition metal oxide, a polymer RAM cell, a RAM cell using perovskite, and a ferroelectric RAM cell using a ferroelectric capacitor.

6. The resistive memory apparatus of claim 1, wherein output terminals of the plurality of power supply circuits are commonly coupled to the I/O circuit.

7. The resistive memory apparatus of claim 1, wherein the partitions and the plurality of power supply circuits are alternately arranged.

8. The resistive memory apparatus of claim 1, wherein a same level of operation voltage is provided to all memory cells within a partition.

9. A resistive memory apparatus comprising:
a memory circuit divided into a plurality of partitions;
a plurality of power supply circuits each arranged next to at least one partition of the plurality of partitions; and
an output circuit to which output terminals of the plurality of power supply circuits are commonly coupled.

10. The resistive memory apparatus of claim 9, wherein the plurality of power supply circuits are configured in a one-to-one correspondence with the plurality of partitions.

11. The resistive memory apparatus of claim 9 further comprising an output circuit arranged on one side of the memory circuit and the power supply circuits.

12. The resistive memory apparatus of claim 9, wherein the partitions and the plurality of power supply circuits are alternately arranged.

13. The resistive memory apparatus of claim 9, wherein each of the plurality of partitions includes a plurality of resistive memory cells coupled between at least one word line and at least one bit line, and each of the plurality of power supply circuits is configured to supply a power voltage to the bit line.

14. The resistive memory apparatus of claim 9, wherein each of the plurality of partitions includes a plurality of resistive memory cells coupled between at least one word line and at least one bit line, and each of the plurality of power supply circuits is configured to supply a read voltage, a first write voltage, and a second write voltage to the bit line of the partition corresponding to the power supply circuit.

15. The resistive memory apparatus of claim 9, wherein an operation voltage supplied to each partition of the plurality of partitions has a same level.

16. The resistive memory apparatus of claim 9, wherein the output terminals of the plurality of power supply circuits are commonly coupled to the I/O circuit.
